(19) United States
(12) Patent Application Publication
(10) Pub. No.: US 2026/0290471 A1
(43) Pub. Date: Sep. 24, 2026

(54) MEMORY SYSTEM, CONTROL METHOD, AND MEMORY CONTROLLER

(71) Applicant: Kioxia Corporation, Tokyo (JP)

(72) Inventor: Masayasu KAWASE, Kawasaki Kanagawa (JP)

(73) Assignee: Kioxia Corporation, Tokyo (JP)

(21) Appl. No.: 19/328,274

(22) Filed: Sep. 15, 2025

(30) Foreign Application Priority Data
Mar. 24, 2025 (JP) 2025-048418

(51) Int. Cl. G11C 16/30; G11C 5/14; G11C 16/10; G11C 16/26; G11C 16/32

(52) U.S. Cl. CPC G11C 16/30; G11C 5/141; G11C 16/102; G11C 16/26; G11C 16/32

(57) ABSTRACT

A memory system to which power is supplied from an external power supply and includes a non-volatile memory and a controller. The non-volatile memory includes a plurality of memory cells. The controller writes data to a first memory cell among the plurality of memory cells in a first mode in which data is stored using a first number of bits. In response to a duration of power cutoff from the external power exceeding a threshold, the controller performs a first operation. In the first operation, the data is read from the first memory cell, and the read data is rewritten to a second memory cell among the plurality of memory cells in a second mode in which data is stored using a second number of bits. The second number of bits is smaller than the first number of bits.

### CROSS-REFERENCE TO RELATED APPLICATION

This application is based upon and claims the benefit of priority from Japanese Patent Application No. 2025-048418, filed Mar. 24, 2025, the entire contents of which are incorporated herein by reference.

### FIELD

Embodiments described herein relate generally to a memory system, a control method, and a memory controller.

### BACKGROUND

A memory system including a non-volatile memory including a plurality of memory cells is known. The memory system stores data in the plurality of memory cells of the non-volatile memory. A value of data stored in each memory cell corresponds to a threshold voltage of each memory cell. After data is stored in each memory cell, the threshold voltage of each memory cell may change over time by influence of data retention. It is therefore desired to appropriately manage the threshold voltage of each memory cell in consideration of the influence of data retention.

### BRIEF DESCRIPTION OF THE DRAWINGS

FIG. 1 is a diagram illustrating a configuration of a memory system according to an embodiment.

FIG. 2 is a diagram indicating a data structure of address conversion information in the embodiment.

FIG. 3 is a diagram illustrating a configuration of a memory cell array in the embodiment.

FIG. 4 is a diagram indicating a data structure of block management information in the embodiment.

FIG. 5 is a diagram indicating a threshold distribution of each mode in the embodiment.

FIG. 6 is a flowchart indicating write processing of the memory system according to the embodiment.

FIG. 7 is a diagram indicating a data structure of rewrite flag information in the embodiment.

FIG. 8 is a flowchart indicating power cutoff processing of the memory system according to the embodiment.

FIG. 9 is a flowchart indicating rewrite processing of the memory system according to the embodiment.

FIG. 10 is a flowchart indicating rewrite processing of a memory system according to a first modification of the embodiment.

FIG. 11 is a flowchart indicating write back processing of a memory system according to a second modification of the embodiment.

FIG. 12 is a diagram indicating a data structure of rewrite flag information in a third modification of the embodiment.

### DETAILED DESCRIPTION

One or more embodiments provide a memory system, a control method, and a memory controller capable of making influence of data retention on each memory cell appropriate.

In general, according to one embodiment, a memory system which includes a non-volatile memory and a controller and to which power is supplied from an external power supply, is provided. The non-volatile memory includes a plurality of memory cells. The controller writes data to a first memory cell among the plurality of memory cells in a first mode. In the first mode, data can be stored using a first number of bits. The controller performs a first operation in response to a duration of power cutoff from the external power supply exceeding a threshold. In the first operation, data is read from the first memory cell, and the read data is rewritten to a second memory cell among the plurality of memory cells in a second mode. In the second mode, data can be stored using a second number of bits. The second number of bits is smaller than the first number of bits.

A memory system, a control method, and a memory controller according to the embodiment will be described in detail below with reference to the accompanying drawings. Note that the present disclosure is not limited by the embodiment.

### Embodiment

A memory system according to an embodiment includes a non-volatile memory including a plurality of memory cells, and while a threshold voltage of each memory cell may change over time by influence of data retention, an effort for making the influence of data retention on each memory cell appropriate is made.

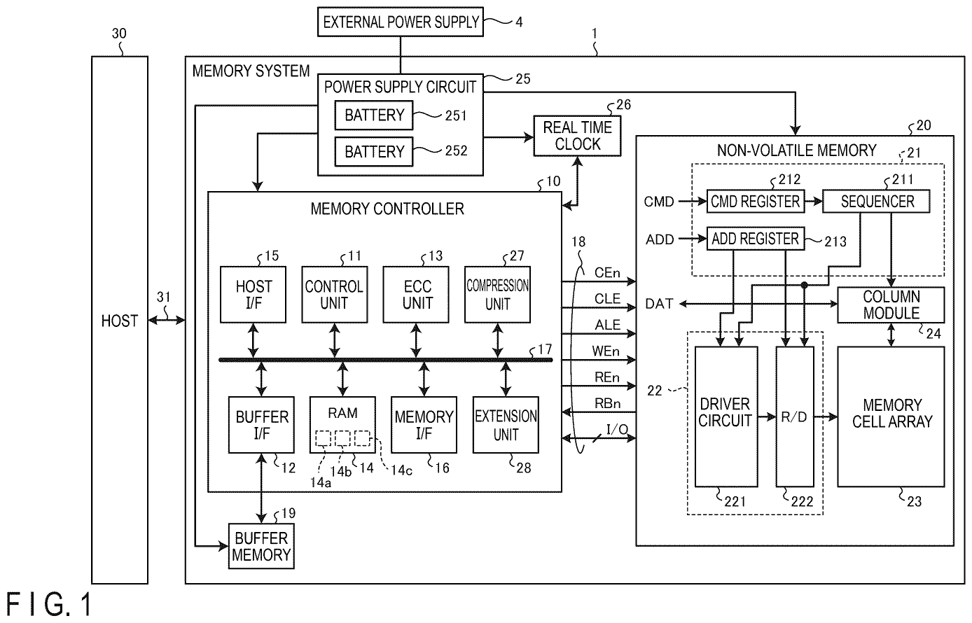

A memory system 1 can be configured as illustrated in FIG. 1. FIG. 1 is a diagram illustrating a configuration of the memory system 1.

The memory system 1 includes a non-volatile memory 20, a memory controller 10, a buffer memory 19, a power supply circuit 25, and a real time clock 26. The memory system 1 can be connected to a host 30. The memory system 1 receives supply of power from an external power supply 4. The external power supply 4 may be provided in the host 30. FIG. 1 illustrates a state where the memory system 1 is connected to the host 30 and the external power supply 4. The host 30 may be, for example, electronic equipment such as a personal computer, a server device, a mobile terminal and a digital still camera.

The memory system 1 is configured with at least the memory controller 10 and the non-volatile memory 20 which are one package or which are mounted on a substrate. The memory system 1 may be various kinds of storage devices including the non-volatile memory 20 such as a solid state drive (SSD), a UFS device and a memory card.

The non-volatile memory 20 is a memory that stores data in a non-volatile manner. The non-volatile memory 20 is, for example, a NAND flash memory. The non-volatile memory 20 can include a plurality of memory chips. In the following description, a case will be described as an example where a NAND flash memory is used as the non-volatile memory 20. As the non-volatile memory 20, a resistive random access memory (ReRAM), a ferroelectric random access memory (FeRAM), a magnetoresistive random access memory (MRAM), or the like, can also be used. Further, the non-volatile memory 20 does not necessarily have to be a semiconductor memory. The present embodiment can be also applied to various storage media other than the semiconductor memory.

The memory controller 10 is, for example, a semiconductor integrated circuit configured as a system-on-a-chip (SoC). Some or all of functions of each component of the memory controller 10 which will be described below may be implemented by a central processing unit (CPU) executing firmware or may be implemented by dedicated hardware.

The memory controller 10 is connected to the host 30 by a host bus 31. The memory controller 10 controls write processing to the non-volatile memory 20 in accordance with a host write command from the host 30. Further, the memory controller 10 controls read processing from the non-volatile memory 20 in accordance with a host read command from the host 30. As standards to be complied with by the host bus 31, for example, arbitrary standards such as peripheral component interconnect express (PCIe™), serial advanced technology attachment (SATA), and serial attached SCSI (SAS) can be employed.

The memory controller 10 is connected to the non-volatile memory 20 by a memory bus 18. The memory bus 18 is used to transmit and receive a signal between the memory controller 10 and the non-volatile memory 20. Specific examples of this signal can include a chip enable signal CEn, a command latch enable signal CLE, an address latch enable signal ALE, a write enable signal WEn, a read enable signal REn, a ready/busy signal RBn, and an input/output signal I/O.

The signal CEn is a signal for enabling a memory chip included in the non-volatile memory 20. The signal CLE is a signal for notifying the non-volatile memory 20 that the input/output signal I/O that is a signal input to the non-volatile memory 20 is a command. The signal ALE is a signal for notifying the non-volatile memory 20 that the input/output signal I/O that is a signal input to the non-volatile memory 20 is an address. The signal WEn is a signal for causing the non-volatile memory 20 to capture the input/output signal I/O that is the input signal. The signal REn is a signal for reading the input/output signal I/O that is an output signal from the non-volatile memory 20. The ready/busy signal RBn is a signal indicating whether the non-volatile memory 20 is in a ready state (a state where a command can be received from the memory controller 10) or in a busy state (a state where a command cannot be received from the memory controller 10). The input/output signal I/O is, for example, a signal of eight bits. The input/output signal I/O is substance of data to be transmitted and received between the non-volatile memory 20 and the memory controller 10. The input/output signal I/O includes a command, an address, write data (data to be written), read data (read data), and a status.

The memory controller 10 includes a host interface (host I/F) 15, a control unit 11, a buffer interface (buffer I/F) 12, a random access memory (RAM) 14, a memory interface (memory I/F) 16, an ECC unit 13, a compression unit 27, and an extension unit 28. The host I/F 15, the control unit 11, the buffer I/F 12, the RAM 14, the memory I/F 16, the ECC unit 13, the compression unit 27, and the extension unit 28 can be connected to each other by an internal bus 17.

The host I/F 15 is connected to the host 30 via the host bus 31. The host I/F 15 transfers a host command and data received from the host 30 respectively to the control unit 11 and the RAM 14 or the buffer memory 19. Further, the host I/F 15 transfers data in the RAM 14 or the buffer memory 19 to the host 30 in response to a request from the control unit 11.

The RAM 14 stores various kinds of management information read from a specific area of the non-volatile memory 20 upon activation, or the like, of the memory system 1. The various kinds of management information include address conversion information 14a and block management information 14b.

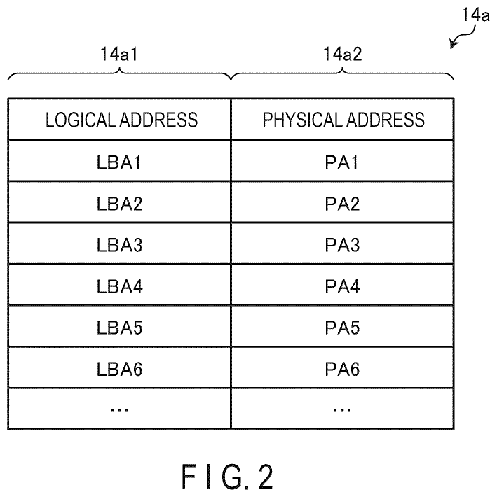

The address conversion information 14a is information including one or more sets of logical addresses and physical addresses which are associated with each other. The address conversion information 14a may be implemented in a table format as indicated in FIG. 2. FIG. 2 is a diagram indicating a data structure of the address conversion information 14a. The address conversion information 14a can be also referred to as a look up table. The address conversion information 14a includes a logical address field 14a1 and a physical address field 14a2. A logical address is recorded in the logical address field 14a1. A physical address is recorded in the physical address field 14a2.

A physical address corresponding to a logical address can be specified by referring to the address conversion information 14a. In the example in FIG. 2, it can be specified that a logical address “LBA1” corresponds to a physical address “PA1”. It can be specified that a logical address “LBA2” corresponds to a physical address “PA2”. Further, it can be specified that a logical address “LBA6” corresponds to a physical address “PA6”.

The block management information 14b will be described later.

The RAM 14 illustrated in FIG. 1 can be used as a working memory that temporarily stores snapshots of various kinds of management information and/or log information that is a change difference of various kinds of management tables. Further, the RAM 14 can be used as a cache memory upon data transfer between the host 30 and the non-volatile memory 20. The RAM 14 can include a dynamic random access memory (DRAM), a static random access memory (SRAM), and the like.

The control unit 11 includes, for example, a central processing unit (CPU). The control unit 11 integrally controls operation of respective units of the memory controller 10. For example, in a case where a host write command is received from the host 30, the control unit 11 issues a write command to the memory I/F 16 to instruct the memory I/F 16 to perform processing of writing data to the non-volatile memory 20. In a case where a host read command is received from the host 30, the control unit 11 issues a read command to the memory I/F 16 to instruct the memory I/F 16 to perform processing of reading data from the non-volatile memory 20. Further, the control unit 11 issues an erase command to the memory I/F 16 to instruct the memory I/F 16 to perform processing of erasing data stored in the non-volatile memory 20 as part of processing of garbage collection (also referred to as compaction) or before issuing a write command. The control unit 11 controls execution of various kinds of processing for managing the non-volatile memory 20, for example, wear levelling, refresh, and patrol read, in addition to garbage collection.

In a case where a host write command is received from the host 30, the control unit 11 determines a storage area on the non-volatile memory 20 for user data to be accumulated in the RAM 14 or the buffer memory 19. Correspondence between a logical address of the user data and a physical address indicating the storage area on the non-volatile memory 20 in which the user data is stored is managed by the address conversion information 14a. This address conversion information 14a is stored in, for example, the non-volatile memory 20, read as necessary and cashed in the RAM 14 and/or the buffer memory 19, or the like. The address conversion information 14a can be updated in accordance with a command from the host 30 (for example, a host write command, a host read command, a host trim command, a host format command) or internal operation (for example, garbage collection operation, refresh operation).

In a case where a host read command is received from the host 30, the control unit 11 converts the logical address designated by the host read command into a physical address using the address conversion information 14a and instructs the memory I/F 16 to read data from the physical address.

The memory I/F 16 is connected to the non-volatile memory 20 via the memory bus 18. The memory I/F 16 controls communication with the non-volatile memory 20. The memory I/F 16 outputs at least the signal ALE, the signal CLE, the signal WEn, or the signal REn to the non-volatile memory 20 according to predetermined procedure in accordance with the command received from the control unit 11. The memory I/F 16 transfers the write command issued by the control unit 11, and write data in the RAM 14 or the buffer memory 19 to the non-volatile memory 20 as the input/output signal I/O upon write processing. The memory I/F 16 transfers the read command issued by the control unit 11 to the non-volatile memory 20 as the input/output signal I/O upon read processing. Further, the memory I/F 16 receives the data read from the non-volatile memory 20 as the input/output signal I/O. The memory I/F 16 transfers the received data to the RAM 14 or the buffer memory 19.

The buffer memory 19 temporarily stores the write data or the read data. The buffer memory 19 has larger capacity than the RAM 14. The buffer memory 19 can include a dynamic random access memory (DRAM), a static random access memory (SRAM), and the like.

The buffer I/F 12 is a controller that controls access to the buffer memory 19 from the memory controller 10. The buffer I/F 12 enables access to, for example, the buffer memory 19 at a double data rate (DDR).

The ECC unit 13 encodes and decodes data for error detection and error correction for the read data. Specifically, upon write processing, the ECC unit 13 encodes data to be written to the non-volatile memory 20 to generate a code word under control by the control unit 11. The code word is written to the non-volatile memory 20. Further, upon read processing, the ECC unit 13 decodes data (that is, the code word) read from the non-volatile memory 20 under control by the control unit 11. The ECC unit 13 executes error detection and error correction on the read data by decoding. The ECC unit 13 notifies the control unit 11 of a failure of error correction in a case where the ECC unit 13 fails in the error correction. As algorithm of encoding and decoding by the ECC unit 13, arbitrary algorism using a reed solomon (RS) code, a Bose-Chaudhuri-Hocquenghem (BCH) code, a low-density parity-check (LDPC) code, or the like, can be applied.

The compression unit 27 compresses the write data (including the parity) before being written to the non-volatile memory 20 under control by the control unit 11. The compression unit 27 compresses the write data in accordance with a reversible compression scheme.

The extension unit 28 extends or decompresses the read data in a compressed state read from the non-volatile memory 20 under control by the control unit 11. The extension unit 28 extends the read data in a compressed state in accordance with an extension scheme corresponding to the reversible compression scheme.

The non-volatile memory 20 includes a command processing unit 21, a drive unit 22, a memory cell array 23, and a column module 24. The command processing unit 21 includes a sequencer 211, a command register (CMD register) 212, an address register (ADD register) 213. The drive unit 22 includes a driver circuit 221 and a row decoder (R/D) 222.

The memory cell array 23 includes a plurality of memory cells (a plurality of memory cell transistors MT). Each memory cell is associated with a row and a column. The memory cell array 23 stores data provided from the memory controller 10.

The row decoder 222 selects a block to be accessed and further selects a row in the selected block.

The driver circuit 221 supplies a voltage to the selected block via the row decoder 222.

The column module 24 includes, for example, a sense amplifier, and a data latch including a plurality of latch circuits. The column module 24 transfers data DAT received from the memory controller 10 to the memory cell array 23 in write operation. Further, the column module 24 senses data read from the memory cell array 23 and obtains the data DAT by performing necessary calculation in read operation. Then, the column module 24 outputs the obtained data DAT to the memory controller 10.

The address register 213 stores an address ADD received from the memory controller 10. The command register 212 stores a command CMD received from the memory controller 10.

The sequencer 211 controls entire operation of the non-volatile memory 20 based on the command CMD stored in the command register 212.

The power supply circuit 25 is connected to the external power supply 4 and includes a battery 251 and a battery 252. The battery 251 is a battery for power loss protection (PLP) and is appropriate for power storage for temporal operation. The battery 252 is a battery for real time clock 26 and is appropriate for power storage for operation for a relatively long period. A period during which operation can be performed based on power storage of the battery 252 is longer than a period during which operation can be performed based on power storage of the battery 251. The battery 251 is, for example, an electric double layer capacitor, an electrolytic capacitor, a ceramic capacitor, or the like. The battery 252 is a primary battery, a secondary battery, or the like.

The power supply circuit 25 supplies power sent from the external power supply 4 to the memory controller 10, the buffer memory 19, the real time clock 26, and the non-volatile memory 20. Further, the power supply circuit 25 supplies power sent from the external power supply 4 to the battery 251 to charge the battery 251. In a case where the battery 252 is a secondary battery, the power supply circuit 25 supplies power sent from the external power supply 4 to the battery 252 to charge the battery 252.

The battery 251 stores power sent from the external power supply 4. In a case where the battery 252 is a secondary battery, the battery 252 stores the power sent from the external power supply 4.

The battery 251 supplies the stored power to at least the memory controller 10 and the non-volatile memory 20 in a case where the power sent from the external power supply 4 is suddenly stopped (in a case where sudden power cutoff occurs). In a case where sudden power cutoff occurs, the battery 252 supplies the stored power to the real time clock 26. A case where sudden power cutoff occurs is, for example, a case where power sent from the external power supply 4 to the power supply circuit 25 is cut off at a timing unintended by a user.

In a case where the host 30 notifies the memory controller 10 of an instruction to shut down the memory system 1, the power supply circuit 25 receives the notification of shutdown from the memory controller 10. The battery 252 supplies the stored power to the real time clock 26 in a case where the power sent from the external power supply 4 is stopped in accordance with the notification of shutdown.

The real time clock 26 operates by receiving power supply from the battery 252 even while a main power supply of the memory system 1 is turned off, and counts a duration of power cutoff. The main power supply is power sent from the external power supply 4. The duration of power cutoff corresponds to, for example, a period during which the memory controller 10 or the non-volatile memory 20 does not operate in the memory system 1.

The real time clock 26 is used to count a relatively long period (for example, several days to several years) during which the memory controller 10 or the non-volatile memory 20 does not operate while the main power supply of the memory system 1 is turned off.

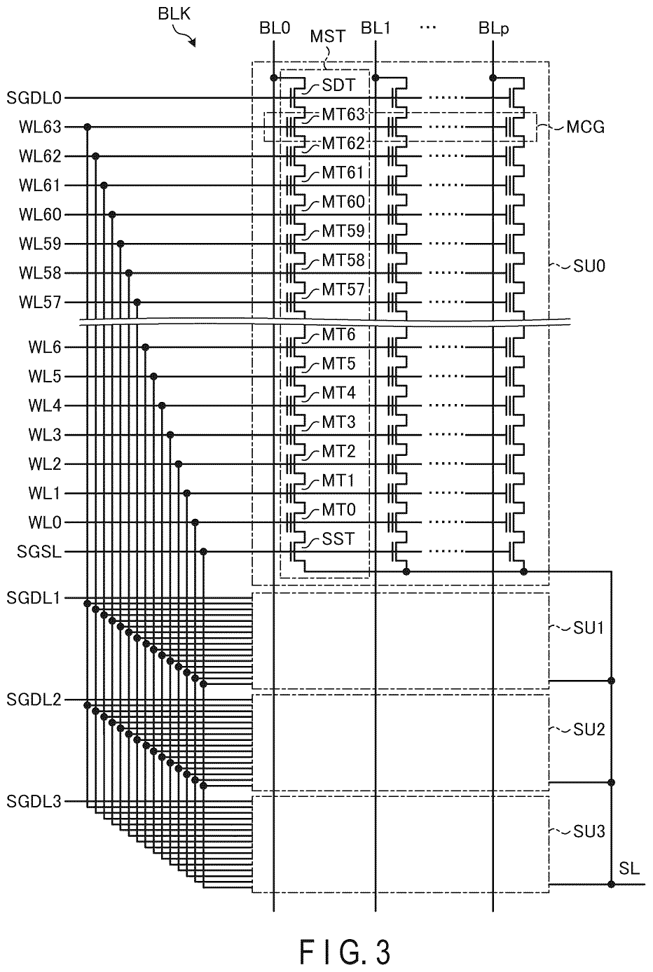

The non-volatile memory 20 may include a plurality of memory chips. Each memory chip includes a memory cell array. The memory cell array includes a plurality of physical blocks. Each physical block is, for example, configured as illustrated in FIG. 3. FIG. 3 is a diagram illustrating a configuration of the memory cell array.

Each physical block BLK includes a plurality of string units SU0 to SU3. The plurality of string units SU0 to SU3 respectively correspond to a plurality of select gate lines SGDL0 to SGDL3. The plurality of string units SU0 to SU3 share a select gate line SGSL. Each of the string units SU0 to SU3 functions as a driving unit in the physical block BLK. The string units SU0 to SU3 can be driven respectively by the corresponding select gate lines SGDL0 to SGDL3 and the select gate line SGSL. Each of the string units SU0 to SU3 includes a plurality of memory strings MST.

Each of the memory strings MST includes, for example, 64 memory cell transistors MT (MT0 to MT63) and two select transistors SDT, SST. The plurality of memory strings MST are connected in parallel between the corresponding bit line BL among bit lines BL0 to BLp and one source line SL. The memory cell transistor MT includes a control gate and a charge storage film and stores data in a non-volatile manner. The 64 memory cell transistors MT (MT0 to MT63) are connected in series between a source of the select transistor SDT and a drain of the select transistor SST. The number of the memory cell transistors MT in the memory string MST is not limited to 64.

Each of word lines WL0 to WL63 (in a case where respective word lines are not distinguished, indicated as WL) commonly connects a control gate of the corresponding memory cell transistor MT between the memory strings MST in each string unit SU in the physical block BLK. In other words, the control gate of the memory cell transistor MT in the same row in each string unit SU in the physical block BLK is connected to the same word line WL. Each string unit SU includes a plurality of memory cell groups MCG respectively corresponding to any of a plurality of word lines WL. Each memory cell group MCG includes (p+1) memory cell transistors MT connected to the same word line WL. In a case where a configuration is employed where a value of one bit can be stored in each memory cell transistor MT (in a case where operation is performed in a single-level cell (SLC) mode), the memory cell group MCG is dealt with as one physical page. In this case, data write operation and data read operation are performed for each physical page.

There is a case where a configuration is employed where a value of a plurality of bits can be stored in each memory cell transistor MT. For example, in a case where a value of n (n≥2) bits can be stored in each memory cell transistor MT, storage capacity per word line WL becomes equal to a size corresponding to n physical pages. In other words, each memory cell group MCG is dealt with as n physical pages. In a multi-level cell (MLC) mode in which a value of two bits is stored in each memory cell transistor MT, data corresponding to two physical pages is stored in each word line WL. In a triple-level cell (TLC) mode in which a value of three bits is stored in each memory cell transistor MT, data corresponding to three physical pages is stored in each word line WL. In a quad-level cell (QLC) mode in which a value of four bits is stored in each memory cell transistor MT, data corresponding to four physical pages is stored in each word line WL. In a penta-level cell (PLC) mode in which a value of five bits is stored in each memory cell transistor MT, data corresponding to five physical pages is stored in each word line WL.

Regarding these modes, the memory controller 10 can perform management in a block BLK unit using the block management information 14b. Here, the mode indicates a write mode in accordance the number of bits of data to be stored in one memory cell transistor MT included in the block BLK.

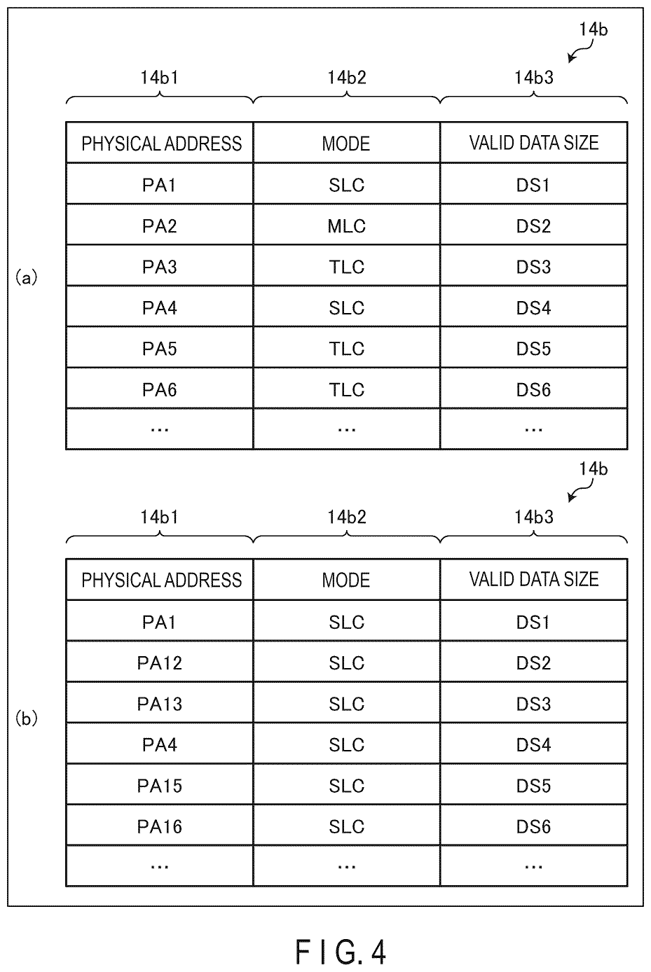

The block management information 14b is information including one or more sets of physical addresses, modes and valid data sizes which are associated with each other. The valid data size is a size of the valid data. The valid data is data stored in the physical address registered in the address conversion information 14a. Alternatively, the valid data can be also said as data stored in the physical address associated with the logical address in the address conversion information 14a. Data stored in the physical address deleted from the address conversion information 14a is invalid data. The invalid data can be also said as data stored in the physical address not associated with the logical address in the address conversion information 14a. The block management information 14b may be implemented in a table format as indicated in FIG. 4. FIG. 4 is a diagram indicating a data structure of the block management information. The block management information 14b includes a physical address field 14b1, a mode field 14b2, and a valid data size field 14b3. A physical address is recorded in the physical address field 14b1. A mode in accordance with the number of bits of data that can be stored in each memory cell transistor MT in the block BLK is recorded in the mode field 14b2. A size of valid data stored in the block BLK is recorded in the valid data size field 14b3.

The mode and the size of the valid data corresponding to the physical address can be specified by referring to the block management information 14b. In the example of the part (a) of FIG. 4, it can be specified that data written in the “SLC” mode is stored in a physical address “PA1”, and a size of the valid data among the data is “DS1”. It can be specified that data written in the “MLC” mode is stored in a physical address “PA2”, and a size of the valid data among the data is “DS2”. Further, it can be specified that data written in the “TLC” mode is stored in a physical address “PA6”, and a size of the valid data among the data is “DS6”.

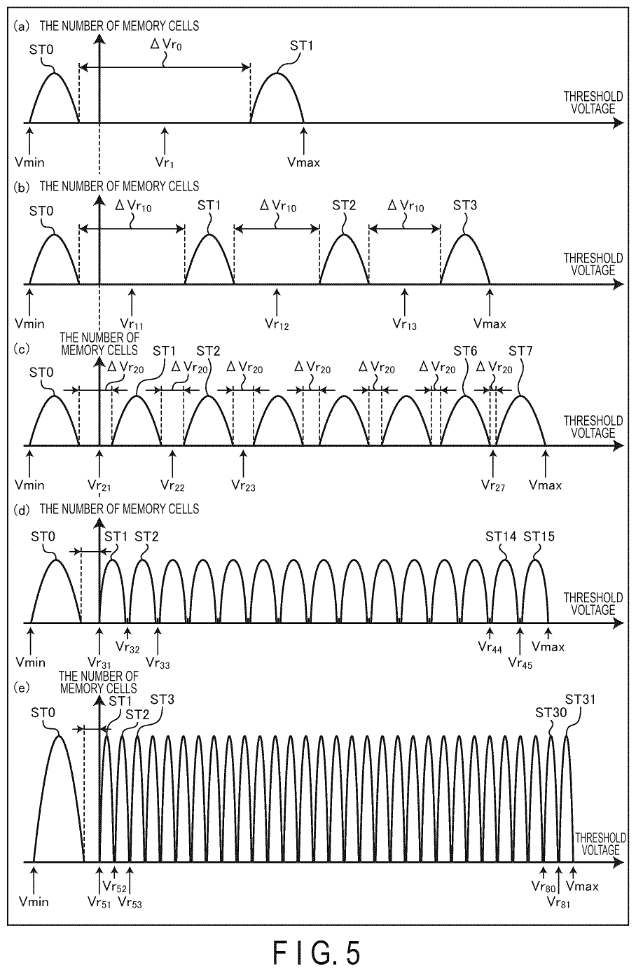

FIG. 5 is a diagram indicating a threshold voltage distribution of the memory cell. As indicated in FIG. 5, as the number of bits of data to be stored in the memory cell increases, a margin for reliability of data retention becomes smaller. The reliability of data retention corresponds to reliability of data stored in the memory cell in a case where the threshold voltage of the memory cell is affected by data retention.

For example, in a case where the memory cell is used in the SLC mode, as indicated in the part (a) of FIG. 5, two states (small regions) ST0 to ST1 exist within a range (range from Vmin to Vmax) in which the threshold voltage is to be controlled. Each state ST indicates a distribution of the threshold voltage of the memory cell. Different values of one bit are associated with respective states ST. The states ST0, ST1 can be respectively associated with values “1 ”, “0” of data. A voltage margin ΔVr0 between the states ST0, ST1 is relatively large, so that large voltage margins between a read voltage Vr1 and the states ST on both sides thereof can be secured. It can be therefore considered that reliability of data retention is relatively high.

In a case where the memory cell is used in the MLC mode, as indicated in the part (b) of FIG. 5, four states ST0 to ST3 exist within the range (range from Vmin to Vmax) in which the threshold voltage is to be controlled. Different values of two bits are associated with the respective states ST. Values of data “11”, . . . , “00” can be respectively associated with the states ST0, . . . , ST3. A voltage margin ΔVr10 between adjacent two states among the states ST0 to ST3 becomes smaller than the voltage margin ΔVr0 in the case of the SLC, and voltage margins between respective read voltages Vr11 to Vr13 and the states ST on both sides thereof become smaller than the voltage margins in the case of the SLC. It can be therefore considered that the reliability of data retention is lower than the reliability of data retention in the SLC mode.

In a case where the memory cell is used in the TLC mode, as indicated in the part (c) of FIG. 5, eight states ST0 to ST7 exist within the range (range from Vmin to Vmax) in which the threshold voltage is to be controlled. Different values of three bits are associated with the respective states ST. Values of data “111”, . . . , “000” can be respectively associated with the states ST0, . . . , ST7. A voltage margin ΔVr20 between adjacent two states among the states ST0 to ST7 becomes smaller than the voltage margin ΔVr10 in the case of the MLC, and voltage margins between the respective voltages Vr21 to Vr27 and the states ST on both sides thereof become smaller than the voltage margins in the case of the MLC. It can be therefore considered that the reliability of data retention is lower than the reliability of data retention in the MLC mode.

In a case where the memory cell is used in the QLC mode, as indicated in the part (d) of FIGS. 5, 16 states ST0 to ST15 exist within the range (range from Vmin to Vmax) in which the threshold voltage is to be controlled. Different values of four bits are associated with the respective states ST. Valus of data “1111”, . . . , “0000” can be respectively associated with the states ST0, . . . , ST15. A voltage margin between adjacent two states among the states ST0 to ST15 is smaller than the voltage margin ΔVr20 in the case of the TLC, and voltage margins between read voltages Vr31 to Vr45 and the states ST on both sides thereof become smaller than the voltage margins in the case of the TLC. It can be therefore considered that the reliability of data retention is lower than the reliability of data retention in the TLC mode.

In a case where the memory cell is used in the PLC mode, as indicated in the part (e) of FIGS. 5, 32 states ST0 to ST31 exist within the range (range from Vmin to Vmax) in which the threshold voltage is to be controlled. Different values of five bits are associated with the respective states ST. Values of data “11111”, . . . , “00000” can be respectively associated with the states ST0, . . . , ST31. A voltage margin between adjacent two states among the states ST0 to ST31 becomes smaller than the voltage margin in the case of the QLC, and voltage margins between read voltages Vr51 to Vr81 and the states ST on both sides thereof become smaller than the voltage margins in the case of the QLC. It can be therefore considered that the reliability of data retention is lower than the reliability of data retention in the QLC mode.

For example, in the memory system 1, as a number of bits stored in the memory cell is larger as indicated in FIG. 5, the reliability of the data retention is likely to degrade. In the memory system 1, if a state of power cutoff continues for a long period, there is a possibility that data may be garbled due to influence of data retention. If the data is garbled, performance of read operation of the memory system 1 for correcting an error bit by the ECC unit 13 can degrade, or data loss due to a correction failure (uncorrectable) by the ECC unit 13 can occur.

Thus, the memory system 1 according to the present embodiment counts the duration of power cutoff, and in a case where the duration of power cutoff exceeds a threshold, mitigates the effects of data retention during power cutoff for a long period by reading data from the target memory cell of the non-volatile memory 20 and rewriting the read data to another memory cell in a mode in which the number of storage bits per memory cell is smaller.

Specifically, in the memory system 1, the memory controller 10 writes data to a memory cell transistor MT_A in a mode MD_A in accordance with a host write command. In the mode MD_A, data can be stored in the memory cell with the number of bits BT_A.

If the memory system 1 is in a power cutoff state, the real time clock 26 operates using power of the battery 252. The real time clock 26 activates a timer and starts counting a duration of power cutoff.

The real time clock 26 confirms the timer and determines whether the duration of power cutoff reaches the threshold. In a case where the duration of power cutoff exceeds the threshold, the real time clock 26 activates the memory controller 10 and the non-volatile memory 20 using power of the battery 252.

The memory controller 10 reads data from the memory cell transistor MT_A and performs rewrite processing of rewriting the read data to a memory cell transistor MT_B in a mode MD_B. The memory cell transistor MT_B is a memory cell different from the memory cell transistor MT_A. In the mode MD_B, data can be stored in the memory cell with the number of bits BT_B. The number of bits BT_B is smaller than the number of bits BT_A.

In a case where the rewrite processing is completed, the real time clock 26 shuts down the memory controller 10 and the non-volatile memory 20.

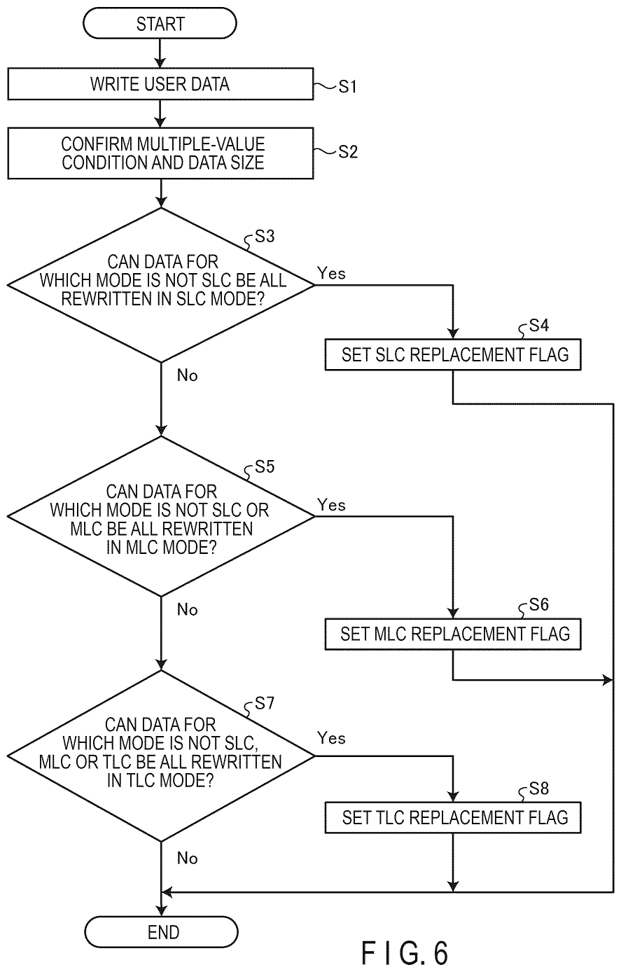

For example, the memory system 1 may perform write processing as indicated in FIG. 6. FIG. 6 is a flowchart indicating the write processing of the memory system.

In the memory system 1, in a case where a host write command is received from the host 30, the memory controller 10 writes user data to the non-volatile memory 20 in accordance with the host write command (S1) and updates the block management information 14b correspondingly.

For example, in a case where data of the valid size “DS6” is written to the physical address “PA6” in the “TLC” mode, the memory controller 10 adds “PA6”, “TLC” and “DS6” respectively to the physical address field 14b1, the mode field 14b2, and the valid data size field 14b3 of the block management information 14b as indicated in the part (a) of FIG. 4.

The memory controller 10 confirms a multiple-value condition and a data size for the user data with reference to the block management information 14b (S2).

The memory controller 10 determines whether data for which the mode is not the SLC can be all rewritten to the SLC mode (S3).

If the number of memory cells to be consumed in accordance with the valid data size is within the number of rewritable memory cells in a case where data is rewritten in the SLC mode, the memory controller 10 determines that the data for which the mode is not the SLC can be all rewritten in the SLC mode (S3: Yes) and sets an SLC rewrite flag (S4). The SLC rewrite flag is a rewrite flag for writing data in the SLC mode. After S4, the write processing ends.

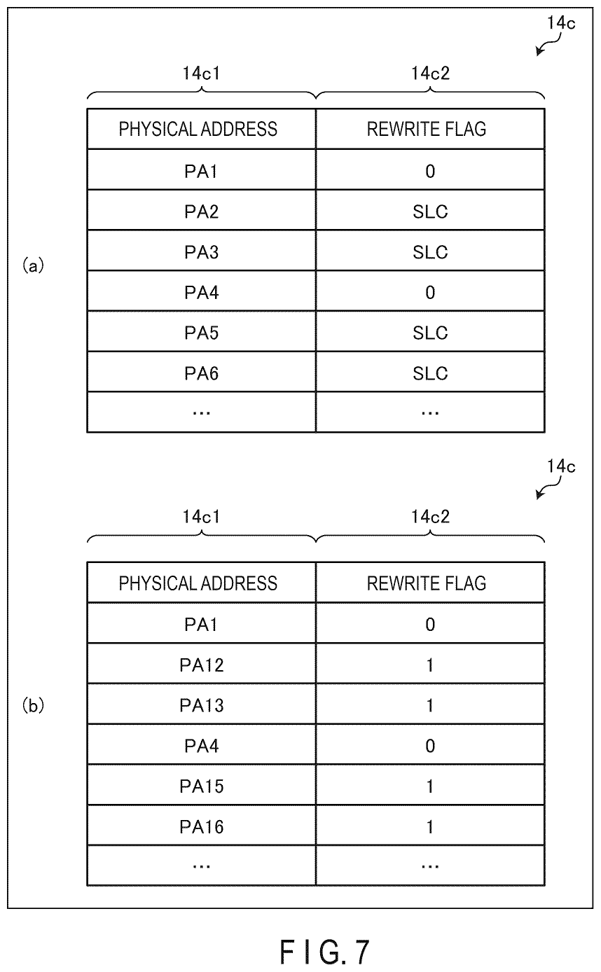

As management information for managing the rewrite flag, the RAM 14 may further store rewrite flag information 14c. The rewrite flag information 14c is information in which one or more physical addresses and the rewrite flags are associated with each other. The rewrite flag information 14c may be implemented in a table format as indicated in FIG. 7. FIG. 7 is a diagram indicating a data structure of the rewrite flag information. The rewrite flag information 14c includes a physical address field 14c1 and a rewrite flag field 14c2. A physical address is recorded in the physical address field 14c1. A rewrite flag is recorded in the rewrite flag field 14c2. The rewrite flag indicates a write mode to be used upon rewriting.

For example, in the example of the block management information 14b in the part (a) of FIG. 4, modes (MLC, TLC) other than the SLC are stored for physical addresses PA2, PA3, PA5, and PA6. If the number of memory cells to be consumed in accordance with the valid data sizes DS2, DS3, DS5, and DS6 is within the number of rewritable memory cells in a case where data is rewritten in the SLC mode, the memory controller 10 determines that data for which the mode is not the SLC can be all rewritten in the SLC mode. As indicated in the part (a) of FIG. 7, the memory controller 10 records the rewrite flag “SLC” in the rewrite flag fields 14c2 corresponding to the physical addresses PA2, PA3, PA5, and PA6.

In S3 in FIG. 6, if the number of memory cells to be consumed in accordance with the valid data size in a case where data is rewritten in the SLC mode is insufficient relative to the number of rewritable memory cells, the memory controller 10 determines that data for which the mode is not the SLC cannot be all rewritten in the SLC mode (S3: No). Then, the memory controller 10 determines whether data for which the mode is not the SLC or the MLC can be all rewritten in the MLC mode (S5).

If the number of memory cells to be consumed in accordance with the valid data size in a case where data is rewritten in the MLC mode is within the number of rewritable memory cells, the memory controller 10 determines that data for which the mode is not the SLC or the MLC can be all rewritten in the MLC mode (S5: Yes) and sets an MLC rewrite flag (S6). The MLC rewrite flag is a rewrite flag for writing data in the MLC mode. After S6, the write processing ends.

If the number of memory cells to be consumed in accordance with the valid data size in a case where data is rewritten in the MLC mode is insufficient relative to the number of rewritable memory cells, the memory controller 10 determines that data for which the mode is not the SLC or the MLC cannot be all rewritten in the MLC mode (S5: No). Then, the memory controller 10 determines whether data for which the mode is not the SLC, the MLC or the TLC can be all rewritten in the TLC mode (S7).

If the number of memory cells to be consumed in accordance with the valid data size in a case where data is rewritten in the TLC mode is within the number of rewritable memory cells, the memory controller 10 determines that data for which the mode is not the SLC, the MLC or the TLC can be all rewritten in the TLC mode (S7: Yes) and sets a TLC rewrite flag (S8). The TLC rewrite flag is a rewrite flag for writing data in the TLC mode. After S8, the write processing ends.

If the number of memory cells to be consumed in accordance with the valid data size in a case where data is rewritten in the TLC mode is insufficient relative to the number of rewritable memory cells, the memory controller 10 determines that data for which the mode is not the SLC, the MLC or the TLC cannot be all rewritten in the TLC mode (S7: No). Then, the write processing ends.

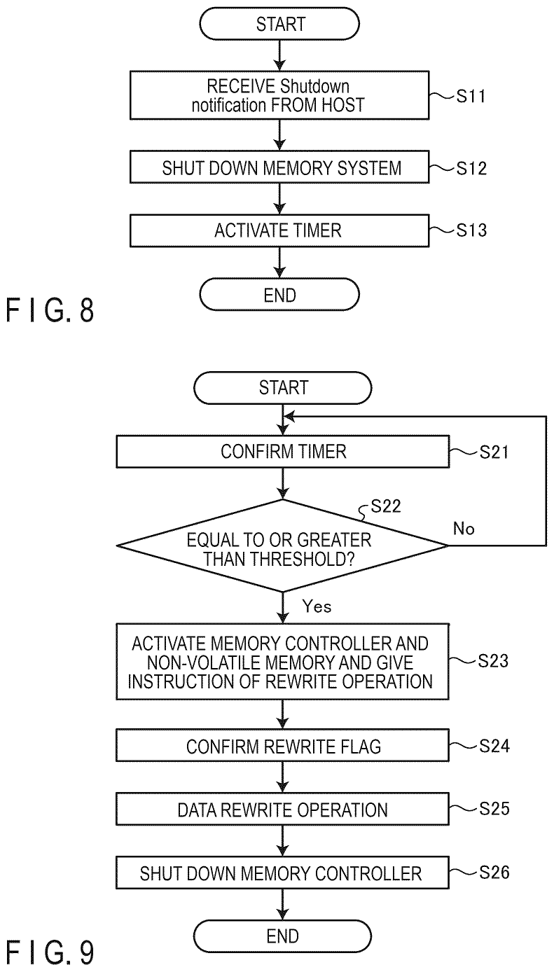

The memory system 1 may perform power cutoff processing as indicated in FIG. 8. FIG. 8 is a flowchart indicating the power cutoff processing of the memory system.

In the memory system 1, if a Shutdown notification is received from the host 30 (S11), the memory controller 10 executes necessary processing and then cuts off power supply to the memory controller 10, the buffer memory 19 and the non-volatile memory 20 from the power supply circuit 25 and shuts down the memory system 1 (S12). The memory system 1 is put into a power cutoff state correspondingly.

If the memory system 1 is put into a power cutoff state, the real time clock 26 operates using power of the battery 252, activates the timer (S13) and starts counting a duration of power cutoff. Then, the power cutoff processing ends.

The memory system 1 may perform rewrite processing as indicated in FIG. 9 during power cutoff. FIG. 9 is a flowchart indicating the rewrite processing of the memory system.

In the memory system 1, the real time clock 26 confirms the timer (S21) and determines whether the duration of power cutoff reaches a threshold (S22). In a case where the duration of power cutoff is less than the threshold (S22: No), the processing of the real time clock 26 returns to S21. In a case where the duration of power cutoff is equal to or greater than the threshold (S22: Yes), the real time clock 26 activates at least the memory controller 10 and the non-volatile memory 20 using power of the battery 252 and instructs the memory controller 10 to perform rewrite operation (S23).

The memory controller 10 reads the address conversion information 14a, the block management information 14b, and the rewrite flag information 14c from the non-volatile memory 20 to the RAM 14 in accordance with the instruction of the rewrite operation, confirms the rewrite flag (S24) and performs data rewrite operation in accordance with the rewrite flag (S25).

For example, in a case indicated in the part (a) of FIG. 7, the SLC rewrite flag is set for the physical addresses PA2, PA3, PA5 and PA6.

In accordance with this, the memory controller 10 issues a read command designating the physical addresses PA2, PA3, PA5 and PA6 as addresses and supplies the read command to the non-volatile memory 20.

The non-volatile memory 20 reads data from the physical addresses PA2, PA3, PA5 and PA6 in accordance with the read command and returns the read data to the memory controller 10.

The memory controller 10 allocates other physical addresses PA12, PA13, PA15, and PA16 as new storage destinations of the read data and updates the address conversion information 14a. The memory controller 10 issues a write command including a size of the data and designation of the physical addresses PA12, PA13, PA15, and PA16, and designation of the SLC mode and supplies the write command and the data to the non-volatile memory 20.

The non-volatile memory 20 rewrites the data to the physical addresses PA12, PA13, PA15, and PA16 in the SLC mode in accordance with the write command. In other words, the data stored in the physical addresses PA2, PA3, PA5, and PA6 is respectively rewritten to the physical addresses PA12, PA13, PA15, and PA16 in the SLC mode. The non-volatile memory 20 returns a write completion notification to the memory controller 10.

The memory controller 10 updates the block management information 14b and the rewrite flag information 14c in accordance with the write completion notification.

For example, the memory controller 10 rewrites the physical addresses PA2, PA3, PA5, and PA6 indicated in the part (a) of FIG. 4 to the physical addresses PA12, PA13, PA15, and PA16 as indicated in the part (b) of FIG. 4 and rewrites the modes in the mode fields 14b2 corresponding to the physical addresses PA12, PA13, PA15, and PA16 to the SLC. The memory controller 10 rewrites the physical addresses PA2, PA3, PA5, and PA6 indicated in the part (a) of FIG. 7 to the physical addresses PA12, PA13, PA15, and PA16 as indicated in the part (b) of FIG. 7 and rewrites values in the rewrite flag fields 14c2 corresponding to the physical addresses PA12, PA13, PA15, and PA16 to a value “1” indicating waiting for write back.

The memory controller 10 transfers the write completion notification to the real time clock 26.

In a case where the real time clock 26 receives the write completion notification, the real time clock 26 shuts down the memory controller 10 and the non-volatile memory 20 (S26). Then, the rewrite processing ends.

As described above, in the present embodiment, in the memory system 1, a duration of power cutoff is counted, and in a case where the duration of power cutoff exceeds the threshold, data is read from the memory cell, and the read data is rewritten in another memory in a mode in which the number of storage bits is smaller. This can improve data retention characteristics in accordance with the duration of power cutoff being long, so that it is possible to reduce a case where data is garbled due to long-period power cutoff. This results in making it possible to prevent degradation of performance and data loss due to data being garbled as a result of data retention.

Note that in a case where data for which the mode is not the SLC, the MLC or the TLC cannot be all rewritten in the TLC mode in the write processing in FIG. 6 (S7: No), the rewrite flag may be set to a limited partial area of the memory cell array 23. For example, the rewrite flag (for example, the TLC rewrite flag) may be set to the limited memory cell transistor MT in which data is written in a mode with a relatively large number of storage bits (such as PLC and QLC), or the physical block BLK including the limited memory cell transistor MT. This can improve data retention characteristics upon long-period power cutoff while securing storage capacity.

Alternatively, the threshold to be used in S22 in FIG. 9 may be experimentally determined in advance before shipment and set in the real time clock 26 or may be able to be set in the real time clock 26 ex post facto by an external command, or the like, after shipment.

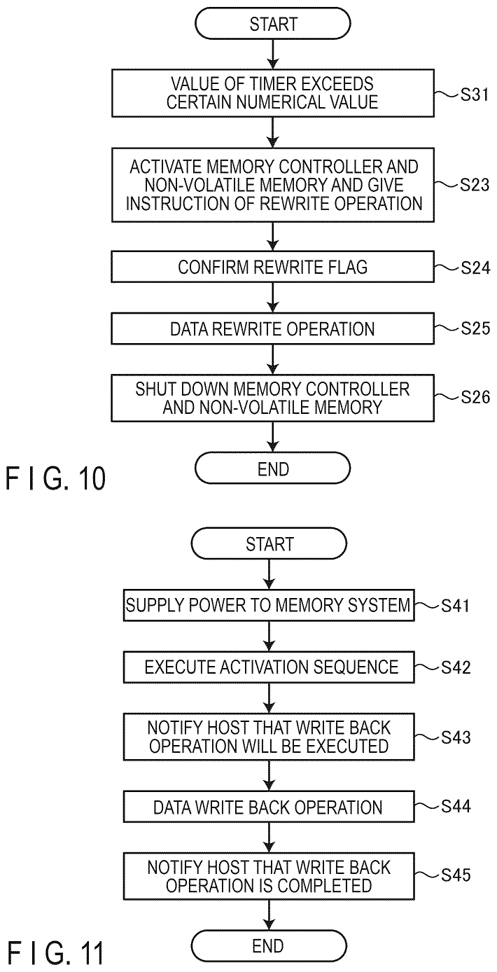

Alternatively, as a first modification of the embodiment, in the real time clock 26, a trigger of starting S23 in FIG. 9 may be configured in a hardware manner. For example, the memory system 1 may perform rewrite processing as indicated in FIG. 10. FIG. 10 is a flowchart indicating the rewrite processing of the memory system according to the first modification of the embodiment.

In the memory system 1, if a value of the timer exceeds a certain numerical value that is a fixed value (S31), the real time clock 26 activates at least the memory controller 10 and the non-volatile memory 20 using power of the battery 252 and instructs the memory controller 10 to perform rewrite operation (S23). Then, the processing in S24 and subsequent processing are performed.

In this manner, as a result of the trigger of starting S23 being configured in a hardware manner, a speed of the rewrite processing can be easily increased.

Alternatively, as a second modification of the embodiment, write back processing as indicated in FIG. 11 may be performed. FIG. 11 is a flowchart indicating the write back processing of the memory system according to the second modification of the embodiment. The write back processing indicated in FIG. 11 is executed in accordance with start of power supply to the memory system 1 after the rewrite processing indicated in FIG. 9 or FIG. 10 is performed.

If power supply from the external power supply 4 to the memory system 1 is started (S41), the memory controller 10 starts execution of an activation sequence (S42). The memory controller 10 notifies the host 30 that the write back operation will be executed after performing predetermined processing in the activation sequence (S43). This enables the host 30 to wait to transmit a host command, and the like, until a timing at which the write back operation is expected to be completed.

After the notification of the write back operation (S43), the memory controller 10 reads the address conversion information 14a, the block management information 14b, and the rewrite flag information 14c to the RAM 14 from the non-volatile memory 20, confirms the rewrite flag and performs data write back operation in accordance with the rewrite flag (S44).

For example, in a case indicated in the part (b) of FIG. 7, the rewrite flag “1” (waiting for write back) is set for the physical addresses PA12, PA13, PA15, and PA16.

In accordance with this, the memory controller 10 issues a read command each designating the physical addresses PA12, PA13, PA15, and PA16 and supplies each of the read command to the non-volatile memory 20.

The non-volatile memory 20 reads data from the physical addresses PA12, PA13, PA15, and PA16 in accordance with the read command and returns the read data to the memory controller 10.

The memory controller 10 allocates other physical addresses PA22, PA23, PA25, and PA26 to the read data and updates the address conversion information 14a. The memory controller 10 issues a write command including a size of the data, each designation of the physical addresses PA22, PA23, PA25, and PA26, and, for example, designation of the MLC mode and supplies each of the write command to the non-volatile memory 20.

The non-volatile memory 20 rewrites the data to the physical addresses PA22, PA23, PA25, and PA26 in the MLC mode in accordance with each of the write command. The non-volatile memory 20 returns a write completion notification to the memory controller 10.

The memory controller 10 updates the block management information 14b and the rewrite flag information 14c in accordance with the write completion notification. The address conversion information 14a may be updated at this timing.

For example, the memory controller 10 respectively rewrites the physical addresses PA12, PA13, PA15, and PA16 to the physical addresses PA22, PA23, PA25, and PA26 in the block management information 14b and respectively rewrites the modes in the mode fields 14b2 corresponding to the physical addresses PA22, PA23, PA25, and PA26 to the MLC. The memory controller 10 respectively rewrites the physical addresses PA12, PA13, PA15, and PA16 to the physical addresses PA22, PA23, PA25, and PA26 in the rewrite flag information 14c and respectively rewrites values in the rewrite flag fields 14c2 corresponding to the physical addresses PA22, PA23, PA25, and PA26 to 0 (invalid).

If the memory controller 10 receives the write completion notification, the memory controller 10 notifies the host 30 that the write back operation is completed (S45). Then, the write back processing ends.

In this manner, in the memory system 1, data can be written back in a mode in which the number of storage bits is larger in accordance with power-on, and storage capacity can be secured.

Alternatively, as a third modification of the embodiment, data compression operation may be performed in addition to operation of rewriting data in a mode in which the number of storage bits is smaller.

For example, in the write processing indicated in FIG. 6, determination may be performed in S3, S5, and S7 with data compression taken into account as well, and a compression flag may be set in S4, S6, and S8 in addition to the rewrite flag. In accordance with this, in the rewrite processing indicated in FIG. 9 or FIG. 10, the compression flag may be confirmed along with the rewrite flag in S24, and data compression operation may be performed before data rewrite operation in S25. Further, in the write back processing indicated in FIG. 11, data extension operation may be performed in the middle of the data write back operation.

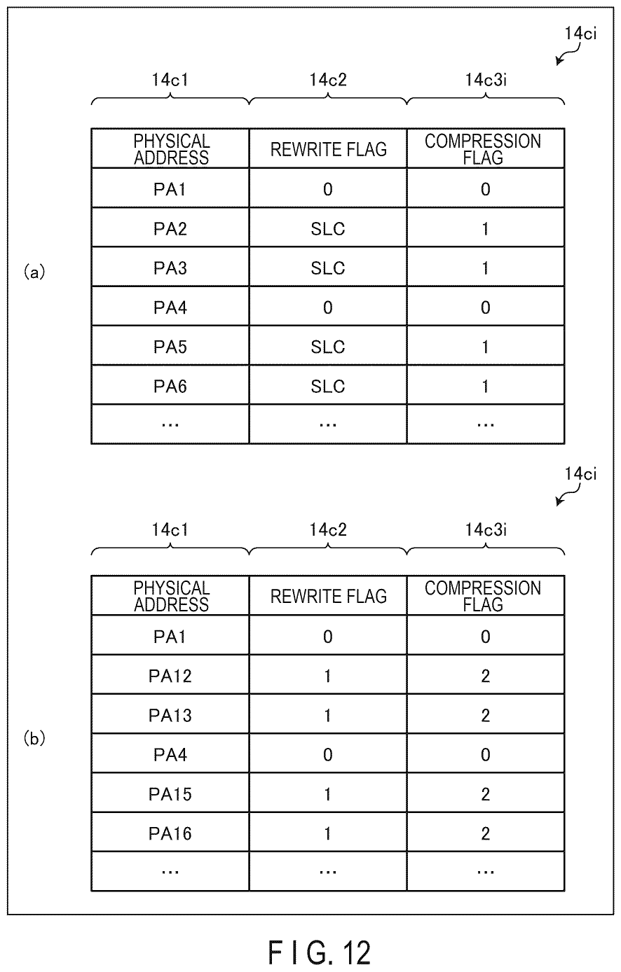

At this time, the rewrite flag information 14ci may be information in which one or more physical addresses, the rewrite flags, and the compression flags are associated with each other. The rewrite flag information 14ci may be implemented in a table format as indicated in FIG. 12. FIG. 12 is a diagram indicating a data structure of the rewrite flag information according to the third modification of the embodiment. The rewrite flag information 14ci further includes a compression flag field 14c3i. Whether or not compression is performed is recorded in the compression flag field 14c3i.

For example, in a case where compression operation should be performed on data of the physical addresses PA2, PA3, PA5, and PA6, as indicated in the part (a) of FIG. 12, a value “1” indicating waiting for compression can be recorded in the compression flag fields 14c3i corresponding to the physical addresses PA2, PA3, PA5, and PA6 in the rewrite flag information 14ci. Further, in a case where compression operation is performed on data of the physical addresses PA12, PA13, PA15, and PA16, as indicated in the part (b) of FIG. 12, a value “2” indicating waiting for extension can be recorded in the compression flag fields 14c3i corresponding to the physical addresses PA12, PA13, PA15, and PA16 in the rewrite flag information 14ci.

In this manner, by also performing data compression operation along with the operation of rewriting data in a mode in which the number of storage bits is smaller, it is possible to improve data retention characteristics upon long-period power cutoff while securing storage capacity.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A memory system to which power is supplied from an external power supply, the memory system comprising:
a non-volatile memory including a plurality of memory cells; and
a controller configured to:
write data to a first memory cell among the plurality of memory cells in a first mode in which data is stored using a first number of bits, and,
in response to a duration of power cutoff from the external power supply exceeding a threshold, perform a first operation of reading the data from the first memory cell and rewriting the read data to a second memory cell among the plurality of memory cells in a second mode in which data is stored using a second number of bits smaller than the first number of bits.

2. The memory system of claim 1, further comprising:
a first battery having first power storage capacity and
a second battery having second power storage capacity larger than the first power storage capacity, the second battery being used when the threshold has been exceeded.

3. The memory system of claim 1, further comprising:
a battery; and
a clock configured to count the duration of the power cutoff,
wherein the controller performs the first operation using power of the battery while power from the external power supply is cut off.

4. The memory system of claim 1, wherein the controller is further configured to, in response to power being restored from the external power supply after the first operation:
perform a second operation of reading the data from the second memory cell and rewriting the read data to a third memory cell among the plurality of memory cells in a third mode in which data can be stored with a third number of bits larger than the second number of bits.

5. The memory system of claim 4, wherein the third mode is the same as the first mode.

6. The memory system of claim 4, further comprising a host interface, wherein the controller is configured to notify a host via the host interface that the second operation will be executed prior to performing the second operation.

7. The memory system of claim 1, wherein the controller is configured to limit the performance of the first operation in accordance with available capacity of rewriting in the second mode.

8. The memory system of claim 1, wherein the controller is configured to compress the data read from the first memory cell before rewriting the read data to the second memory cell.

9. The memory system of claim 8, wherein the controller is further configured to, after the compressed data is read from the second memory cell, perform an extension operation on the compressed data.

10. The memory system of claim 1, wherein the controller is configured to:
maintain management information that associates physical addresses with a corresponding storage mode; and
update the management information after performing the first operation.

11. The memory system of claim 10, wherein the management information includes a rewrite flag to identify a corresponding storage mode of the data that has been rewritten to the second mode.

12. A control method for a memory system that includes a non-volatile memory including a plurality of memory cells and that is supplied with power from an external power supply, the method comprising:
writing data to a first memory cell among the plurality of memory cells in a first mode in which data is stored using a first number of bits;
monitoring a duration of power cutoff from the external power supply; and
in response to the duration of power cutoff from the external power supply exceeding a threshold, performing a first operation of reading the data from the first memory cell and rewriting the read data to a second memory cell among the plurality of memory cells in a second mode in which data is stored using a second number of bits smaller than the first number of bits.

13. The method of claim 12, further comprising, in response to power being restored from the external power supply after the first operation:
performing a second operation of reading the data from the second memory cell and rewriting the read data to a third memory cell among the plurality of memory cells in a third mode in which data can be stored with a third number of bits larger than the second number of bits.

14. The method of claim 12, further comprising limiting the performance of the first operation in accordance with available capacity of rewriting in the second mode.

15. The method of claim 12, further comprising compressing the data read from the first memory cell before rewriting the read data to the second memory cell.

16. The method of claim 12, further comprising,
maintaining management information that associates physical addresses with a corresponding storage mode; and
updating the management information after performing the first operation.

17. A memory controller for controlling a non-volatile memory having a plurality of memory cells, the memory controller comprising:
a memory interface configured to communicate with the non-volatile memory; and
a control circuit coupled to the memory interface, the control circuit configured to:
instruct the memory interface to write data to a first region of a part of the plurality of memory cells of the non-volatile memory in a first mode in which data is stored with a first number of bits per memory cell; and
in response to detecting that a power-off duration of the non-volatile memory has exceeded a threshold, instruct the memory interface to read the data from the first region and write the read data to a second region of another part of the plurality of memory cells of the non-volatile memory in a second mode in which data is stored with a second number of bits per memory cell, the second number of bits being fewer than the first number of bits.

18. The memory controller of claim 17, wherein the control circuit is further configured to, in response to power being restored from the external power supply after the first operation:
perform a second operation of reading the data from the second memory cell and rewriting the read data to a third memory cell among the plurality of memory cells in a third mode in which data can be stored with a third number of bits larger than the second number of bits.

19. The memory controller of claim 17, wherein the control circuit is configured to limit the performance of the first operation in accordance with available capacity of rewriting in the second mode.

20. The memory controller of claim 17, wherein the control circuit is configured to compress the data read from the first memory cell before rewriting the read data to the second memory cell.
